(19) United States
(12) Patent Application Publication
(10) Pub. No.: US 2023/0299127 A1
(43) Pub. Date: Sep. 21, 2023

(54) INTEGRATED CIRCUIT COMPRISING A HIGH VOLTAGE TRANSISTOR AND CORRESPONDING MANUFACTURING METHOD

(71) Applicant: STMicroelectronics (Rousset) SAS, Rousset (FR)

(72) Inventors: Francois TAILLIET, Fuveau (FR); Loic WELTER, Chateauneuf-le-Rouge (FR); Maria-Paz DUMITRESCU, Pourrieres (FR); Roberto SIMOLA, Trets (FR)

(73) Assignee: STMicroelectronics (Rousset) SAS, Rousset (FR)

(21) Appl. No.: 18/180,025

(22) Filed: Mar. 7, 2023

(30) Foreign Application Priority Data
Mar. 15, 2022 (FR) 2202260

(51) Int. Cl. H01L 29/06; H01L 29/78; H01L 27/092; H01L 29/66; H01L 29/40; H01L 29/423; H01L 21/28; H01L 29/788; H01L 21/762; H10B 41/10; H10B 41/35

(52) U.S. Cl. CPC H01L 29/0607; H01L 29/7835; H01L 27/0922; H01L 29/6659; H01L 29/402; H01L 29/42324; H01L 29/40114; H01L 29/66825; H01L 29/7883; H01L 21/76224; H10B 41/10; H10B 41/35

(57) ABSTRACT

The integrated circuit comprises at least one transistor including a separate gate structure and field plate, disposed on a front face of a semiconductor substrate, and a doped conduction region in the semiconductor substrate located plumb with an edge of the gate structure and plumb with an edge of the field plate.

### BACKGROUND

### Technical Field

Embodiments and implementations relate to integrated circuits, in particular high voltage transistors.

### Description of the Related Art

Certain types of integrated circuits use high voltages, that is to say for example voltages greater than 12V (volts), for their operation and are at the same time constrained by the size of their components. This is particularly the case of non-volatile memories which use high voltages for write operations. The high voltages can also be used for decoding operations in memory when the array of memory cells is designed according to a dense mesh of high voltage transistors.

The evolution of transistor morphology tends towards increasingly narrow transistors (without significant reduction in length due to voltage withstand constraints). Reducing the width of the transistor leads to a decrease in the avalanche voltage between the source-drain conduction regions and the substrate, due to a spike effect in the morphology of the doped regions and an increase in the doping concentrations, to satisfy scaling rules following size reductions.

Reference is made in this respect to FIG. 1, illustrating an example of a high-voltage transistor 100 including two levels of stacked and non-self-aligned gates, typically used in non-volatile memories. The high voltage transistor 100 comprises a gate structure including a first gate G1 located on the surface of a semiconductor substrate PSUB and a second gate G2 covering the first gate, and projecting beyond the first gate on the surface of the substrate PSUB. The high voltage transistor 100 includes a conventional drain region D and a Lightly Doped Drain region LDD located under the projecting part of the second gate G2. In a conventional manner and known to the person skilled in the art, the lightly doped drain region LDD is implanted less deeply and with a lower concentration of doping than the conduction region D, and allows to prevent avalanche phenomena at the drain side end of the conduction channel of the transistor 100.

However, with the continuous reductions in the lithographic nodes and the width of the high voltage transistors 100, the avalanche phenomena at the exterior of the drain D become problematic for high voltages used in the operation of the circuits. Indeed, in a zone containing the junction between the drain D and the substrate PSUB on the external side of the drain D, that is to say in a zone BRD located along a lateral isolation region, the spatial variation in the dopant concentration is greater than between the rest of the volume of the substrate PSUB and the conduction region D. Furthermore, in the zone of the junction BRD on the external side of the drain D, the morphology of the junction has a curvature which is even greater as the width of the transistor 100 is small. The width of the transistor 100 corresponds to the extent of the channel region and the drain region D in the direction perpendicular to the section plane of FIG. 1. By an effect comparable to a peak effect, the curvature of the junction in the zone BRD at the end of the transistor 100 contributes to locally increasing the electric field, and consequently to reducing the avalanche voltage. The narrower the transistor, the greater this curvature, and the more the avalanche voltage is locally reduced. However, the evolution of integrated circuits tends towards increasingly narrow transistors (in width).

Consequently, the junction PN between the drain region D and the substrate PSUB includes a locality BRD having a high dopant concentration, and a high curvature morphology, so that the voltage withstand of the junction is locally smaller therein.

However, if the high voltages cannot be reduced to accompany the reduction in size of the transistors, as is the case for the operation of non-volatile memories, then the avalanche voltage becomes a technical blocking point in the reduction in the size of integrated circuit transistors.

Thus there is a need to propose a solution allowing to increase the voltage withstand of high voltage transistors, that is to say to increase the avalanche voltage, while reducing the size of the high voltage transistors.

### BRIEF SUMMARY

According to one aspect, provision is made in this respect of an integrated circuit comprising at least one transistor including a separate gate structure and field plate, disposed on a front face of a semiconductor substrate, and a doped conduction region in the semiconductor substrate located plumb with an edge of the gate structure and plumb with an edge of the field plate.

The field plate allows on the one hand to be able to modulate the electric field present in the semiconductor substrate facing the field plate, by field effect. On the other hand, the field plate allows to extend a definition of a lightly doped region, typically on the channel side of the conduction region, towards the outer side of the conduction region, free of charge in terms of manufacturing steps. Thus, it is possible to benefit from an improvement in the voltage withstand on the edge of the conduction region, in addition to a typical improvement in the voltage withstand on the channel side of the transistor.

In this respect, according to one embodiment, said at least one transistor further includes a lightly doped conduction region implanted in the semiconductor substrate, extending on either side of the conduction region under the gate structure from said edge of the gate structure and under the field plate from said edge of the field plate.

This allows to increase the avalanche voltage of the transistor from 0.5V to 1V free of charge in terms of steps of the manufacturing method.

According to one embodiment, the conduction region has a first dopant concentration and extends into the substrate from the front face to a first depth, and the lightly doped conduction region has a second dopant concentration lower than the first concentration, and extends into the substrate from the front face to a second depth less than the first depth.

According to one embodiment, the gate structure includes a first gate region and a second gate region, the first gate region including a first conductive layer disposed on a first dielectric layer and being located on the front face of the substrate, the second gate region including a second conductive layer disposed on a second dielectric layer, the second gate region including an internal portion on the first gate region and an external portion projecting from the first gate region on the front face of the substrate, the conduction region being located plumb with the edge of the external portion of the second gate region.

According to one embodiment, the lightly doped conduction region extends under the external portion of the second gate region.

According to one embodiment, the field plate comprises a third conductive layer disposed on a third dielectric layer and is located on the front face of the substrate, the third conductive layer having the same composition and the same thickness as the second conductive layer, the third dielectric layer having the same composition and the same thickness as the second dielectric layer of the external portion of the second gate region.

In other words, the field plate is produced by the same steps of method as the second gate region, allowing in particular to mask the implantation of the self-aligned conduction region on the material of the second gate region, so as to hide this implantation under the field plate, and keep the lightly doped conduction region under the field plate.

According to one embodiment, the field plate comprises a third conductive layer disposed on a third dielectric layer and is located on the front face of the substrate, the third conductive layer having the same composition and the same thickness as the first conductive layer, the third dielectric layer having the same composition and the same thickness as the first dielectric layer.

In other words, the field plate is produced by the same method steps as the first gate region, allowing, for example, to form the lightly doped conduction region under the field plate during the implantation of the conduction region, partially passing through the material of the first gate region.

According to one embodiment, the field plate is electrically connected to the conduction region.

This allows to benefit from a field effect in the external part of the conduction region, adapted to increase the avalanche voltage of the transistor additionally and independently of the presence of the lightly doped conduction region.

According to one embodiment, the edge of the field plate opposite said edge plumb with the conduction region is located above a dielectric volume of a shallow isolation trench.

This is advantageous in terms of alignment of the formation of the field plate, and in terms of surface footprint since the field plate partially occupies an inactive surface facing the shallow isolation trench.

According to another aspect, provision is made of a method for manufacturing an integrated circuit comprising at least a formation of a transistor including: a formation of a separate gate structure and field plate, disposed on a front face of a semiconductor substrate; and a formation of a doped conduction region in the semiconductor substrate located plumb with an edge of the gate structure and plumb with an edge of the field plate.

According to one implementation, said at least one formation of the transistor further includes: a formation of a lightly doped conduction region implanted in the semiconductor substrate, extending on either side of the conduction region under the gate structure from said edge of the gate structure and under the field plate from said edge of the field plate.

According to one implementation, the formation of the conduction region comprises an implantation of dopants at a first concentration and with a first energy, and the formation of the lightly doped conduction region comprises an implantation of dopants at a second concentration lower than the first concentration and at a second energy lower than the first energy.

According to one implementation, the formation of the gate structure includes:
a formation of a first dielectric layer on the front face of the substrate, a formation of a first conductive layer on the first dielectric layer and an etching of the first conductive layer delimiting a first gate region,
a formation of a second dielectric layer, a formation of a second conductive layer on the second dielectric layer, and an etching of the second conductive layer delimiting a second gate region, so that the second gate region includes an internal portion on the first gate region and an external portion projecting from the first gate region on the front face of the substrate,
the formation of the conduction region comprising an implantation of self-aligned dopants on the second gate region.

According to one implementation, the formation of the lightly doped conduction region comprises an implantation of self-aligned dopants on the first gate region, before the steps of forming the second gate region.

According to one implementation, the formation of the field plate comprises a formation of a third dielectric layer on the front face of the substrate, a formation of a third conductive layer on the third dielectric layer and an etching of the third conductive layer delimiting the field plate, simultaneously with the respective formations and etching of the second gate region.

According to one implementation, the formation of the field plate comprises a formation of a third dielectric layer on the front face of the substrate, a formation of a third conductive layer on the third dielectric layer and an etching of the third conductive layer delimiting the field plate, simultaneously with the respective formations and etching of the first gate region, the formation of the lightly doped conduction region comprising an implantation of dopants through the field plate during the implantation of the conduction region.

According to one implementation, the method further comprises a formation of an electrical connection between the field plate and the conduction region.

According to one implementation, the method comprises a formation of a dielectric volume of a shallow isolation trench prior to the formation of the field plate, the formation of the field plate comprising a delimitation of the field plate so that the edge of the field plate opposite said edge plumb with the conduction region is located above the dielectric volume of the shallow isolation trench.

### BRIEF DESCRIPTION OF THE SEVERAL VIEWS OF THE DRAWINGS

Other advantages and features of the disclosure will appear upon examining the detailed description of non-limiting embodiments and implementations and the appended drawings, wherein:

FIG. 1 previously described, illustrates a conventional high voltage transistor;

FIG. 2A, 2B illustrates a top view and a cross-sectional view of a transistor adapted to high voltages according to an embodiment;

FIG. 3 illustrates a partial sectional view of the transistor as shown in FIG. 2A, 2B;

FIG. 4A, 4B illustrates a top view and a cross-sectional view of a transistor adapted to high voltages according to an embodiment;

FIG. 5 illustrates a partial sectional view of the transistor as shown in FIG. 4A, 4B;

FIG. 6 illustrates measured results of avalanche voltages between a drain region and a substrate of embodiments of transistors as described in to FIG. 1, FIG. 2A, 2B, and FIG. 4A, 4B;

FIG. 7 illustrates a portion of a memory plane of an EEPROM memory; and

FIG. 8 illustrate embodiments and implementations of the disclosure.

### DETAILED DESCRIPTION

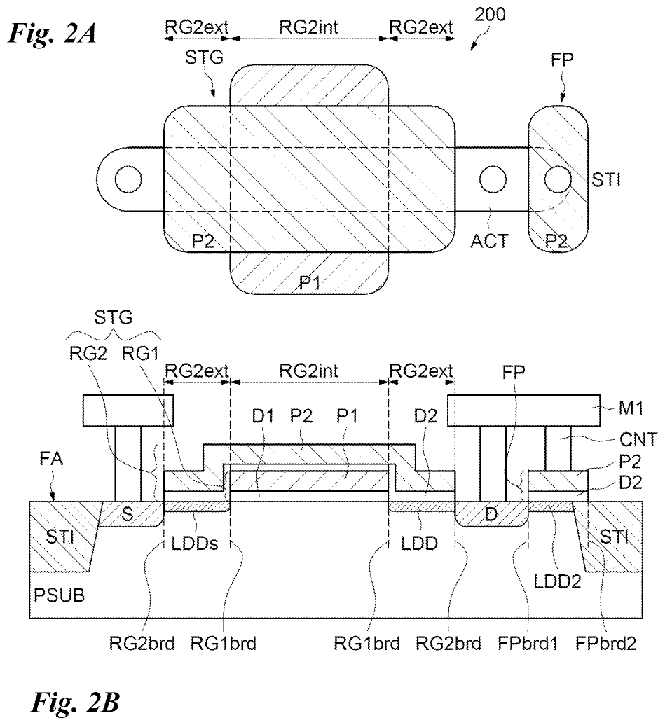

FIG. 2A, 2B illustrates a top view and a cross-sectional view of a first example of a transistor 200 adapted for high voltages, that is to say voltages typically greater than 12V (volts). The transistor 200 is made in an integrated manner, for example in a non-volatile memory integrated circuit of the “EEPROM” (for “Electrically Erasable and Programmable Read Only Memory”) type.

The transistor 200 includes a separate gate structure STG and a field plate FP, disposed on a front face FA of a semiconductor substrate PSUB. The field plate FP is structurally comparable to a typical single gate region of a transistor. The field plate FP is adapted for producing a field effect in the underlying semiconductor substrate (such as a conventional transistor gate), but is not intended to form a conduction channel between two conduction regions (unlike a conventional transistor gate).

The front face FA of the semiconductor substrate PSUB, typically made of P-type doped silicon, is conventionally the face of the substrate from which the components of the integrated circuit are made, in a part usually called “FEOL” (for “Front End Of Line”). The region of the substrate PSUB on the side of the front face FA, in and on which the components of the integrated circuit are made, typically includes doped wells of the same P type as the substrate, and/or doped wells of the opposite N type. In the following, the wells will not be distinguished from the substrate, and they will be referred to by the term “substrate.”

Lateral isolation structures, for example of the shallow isolation trench type (shallow trench isolation (STI)), allow to define an active region ACT in the substrate PSUB, in and facing which the transistor 200 is made. The active region ACT extends in length in a first direction, that is to say the horizontal direction in the orientation of the drawings of FIG. 2A, 2B, and in width perpendicular to the cutting plane of the drawing of FIG. 2A, 2B and in the vertical direction of the orientation of the drawing of the top view of FIG. 2A, 2B. Typically, the length of the active region of the transistor 200 is particularly constrained for the reduction in size of the transistors, since this would involve a reduction in the length of the channel of the transistor, which would reduce the source-drain voltage withstand (usually “Vds”). Moreover, the reduction of the width of the active region ACT conventionally produces a reduction of the avalanche voltage between the drain and the substrate. The transistor 200 is advantageously configured to limit this reduction in avalanche voltage and withstand high voltages higher than conventional transistors.

The transistor 200 includes two conduction regions doped in the semiconductor substrate PSUB on either side of the gate structure STG, that is to say a source region S and a drain region D.

The gate structure STG is on the one hand advantageously configured to withstand high voltages, that is to say in particular not to generate an avalanche phenomenon in the channel region at voltages of the order of 12V, for example voltages comprised between 12V and 13V. The gate structure STG includes in this respect a superimposed first gate region RG1 and second gate region RG2, allowing to obtain lightly doped conduction regions LDD, LDDs in the substrate PSUB having a greater extent under the gate structure STG than conventional single gate region transistors. Usually, the lightly doped conduction regions LDD, LDDs, LDD2 are called “Lightly Doped Drain,” independently of their positions on the source side S or on the drain side D.

The first gate region RG1 includes a first dielectric layer D1, typically made of silicon oxide, located on the front face of the substrate FA and a first conductive layer P1, typically made of polycrystalline silicon, disposed on the first dielectric layer D1.

The second gate region RG2 includes a second dielectric layer D2, typically made of silicon oxide and/or nitride, and a second conductive layer P2, typically made of polycrystalline silicon, disposed on the second dielectric layer D2. The second gate region RG2 covers the entire width of the first gate region RG1 in an internal portion RG2int of the second gate region RG2, and projects on each side of the first gate region RG1, so as to cover the front face of the substrate FA in an external portion RG2ext of the second gate region RG2.

The lightly doped conduction regions LDDs, LDD are located under the external portions RG2ext of the second gate region RG2, and their ends on the transistor channel side are located plumb or transverse with the respective edges of the first gate region RG1.

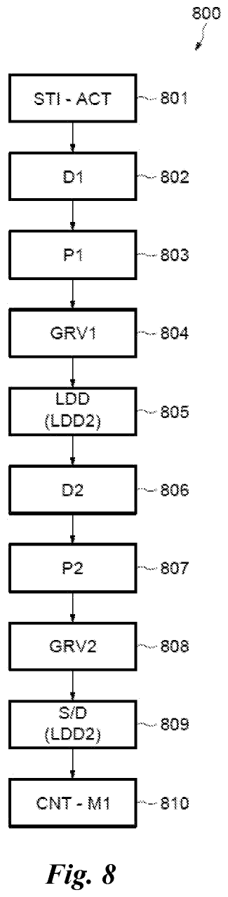

Indeed, as will be seen below in relation to FIG. 8, the first gate region RG1 can act as a self-aligned mask for the implantation of the lightly doped conduction regions LDDs, LDDs.

The drain region D of the transistor 200 is located plumb with an edge of the gate structure STG, that is to say plumb with the edge RG2brd of the external portion RG2ext of the second gate region RG2, and plumb with an edge FPbrd1 of the field plate FP.

Indeed, as will be seen below in relation to FIG. 8, the second gate region RG2 as well as the field plate FP, can act as self-aligned masks for the implantation of the conduction regions S, D.

Also, the field plate FP comprises a “third” dielectric layer D2 located on the front face of the substrate FA and a “third” conductive layer P2 disposed on the third dielectric layer D2.

The definition of the field plate FP may extend outside of the active region ACT in the first direction (that is to say in the direction of the length of the active region ACT), so that the edge FPbrd2 of the field plate FP opposite said edge FRbrd1 plumb with the drain D is located above the dielectric volume of the shallow isolation trench STI.

In this first example of transistor 200, the field plate FP advantageously has the same nature and the same composition as the second gate region RG2. The field plate FP and the second gate region RG2 are in this respect formed during the same manufacturing steps (see FIG. 8). Thus, the third conductive layer P2 has the same composition (polysilicon) and the same (measurable) thickness as the second conductive layer P2, and the third dielectric layer D2 of the field plate FP has the same composition (oxide and/or silicon nitride) and the same (measurable) thickness as the second dielectric layer D2 located at the external part RG2ext of the second gate region RG2.

In this framework, the field plate FP produces precisely the same self-aligned mask effect for the implantation of the conduction regions S, D as the second gate region RG2.

Thus, the extent of the lightly doped conduction region LDDs, LDD, LDD2 is defined by the overflows RG2ext of the second gate region RG2 relative to the first gate region RG1 facing the active region ACT; and by the position of the field plate FP facing the active region ACT.

Consequently, on the side of the drain region D, the lightly doped conduction region LDD, LDD2 extends on either side of the conduction region D, in the first direction, under the gate structure STG from said edge of the second gate region RG2brd and under the field plate FP from said edge of the field plate FPbrd1. On the side of the source region S, the lightly doped conduction region LDDs extends under the gate structure STG, in the first direction, from the edge of the second gate region RG2brd defining the implantation of the source S.

The conduction regions S, D have a first dopant concentration and extend into the substrate PSUB from the front face FA to a first depth. The lightly doped conduction region LDDs, LDD, LDD2 (as is the case with conventional lightly doped drain regions) in turn has a second dopant concentration lower than the first concentration, and extends into the substrate PSUB from the front face FA at a second depth less than the first depth.

Furthermore, the field plate FP is advantageously electrically connected to the drain region D, for example via contact metal pillars CNT and a metal track of a metal level M1.

Indeed, it is typically the drain region D which is subject to avalanche phenomena, given that it is typically on the drain D that the greatest absolute potentials are applied, positively for an N-type transistor and negatively for a P-type transistor, while lower absolute potentials are typically applied to the source.

Consequently, the field effect at the PN junction between the drain and the substrate, generated by the field plate PL at the potential of the drain D, allows to reinforce the voltage withstand of the PN junction, that is to say to increase the avalanche voltage of the transistor 200.

The effect of increasing the avalanche voltage of the transistor 200 by the field plate PL biased to a voltage of the same sign as the voltage of the drain region D is obtained by field effect in the PN junction and is not related to the presence of the lightly doped conduction region LDD2 under the field plate PL.

This being the case, as mentioned previously and described below in relation to FIG. 8, the presence of the field plate PL generates the presence of the lightly doped conduction region LDD2 under the field plate PL, by the self-aligned implantation steps.

Moreover, the presence of the lightly doped conduction region LDD2 under the field plate PL further allows to independently increase the avalanche voltage of the transistor 200.

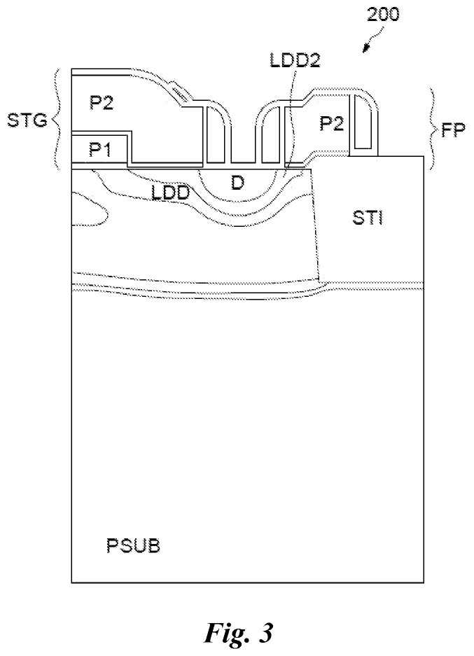

Reference is made in this respect to FIG. 3.

FIG. 3 shows part of the sectional view of the transistor 200 of FIG. 2A, 2B which shows the concentration of dopants in the substrate PSUB, and in particular in the drain region D and the lightly doped conduction region LDD, LDD2 under the gate structure STG and under the field plate FP. The dopant concentration is shown schematically by “isopleth” lines of equal concentrations of N-type dopants (for example, for the case of an N-type transistor), with the smallest concentration at the substrate PSUB and the greatest concentration at the drain D.

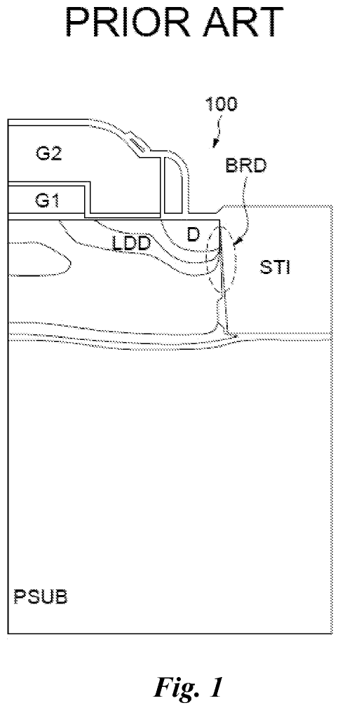

The presence of the lightly doped conduction region LDD2, in particular under the field plate FP, has the consequence that the variation in the concentration of dopants between the drain region D and the substrate PSUB, in particular at the edge of the shallow isolation region STI, is spatially more gradual than in conventional transistors 100 as shown in FIG. 1.

Indeed, the morphology of the concentrations of dopants around the drain region D, LDD, LDD2 is substantially the same on the side of the gate structure STG as on the side of the field plate FP. Thus, in the transistor 200, the variation in the concentration of the dopants between the drain region D and the volume of the substrate PSUB is substantially the same in all directions of the volume.

Consequently, the junction PN between the drain region D and the substrate PSUB does not include a high dopant concentration locality, and the PN junction between the drain region D and the substrate PSUB is able to withstand higher voltages without producing avalanche phenomenon.

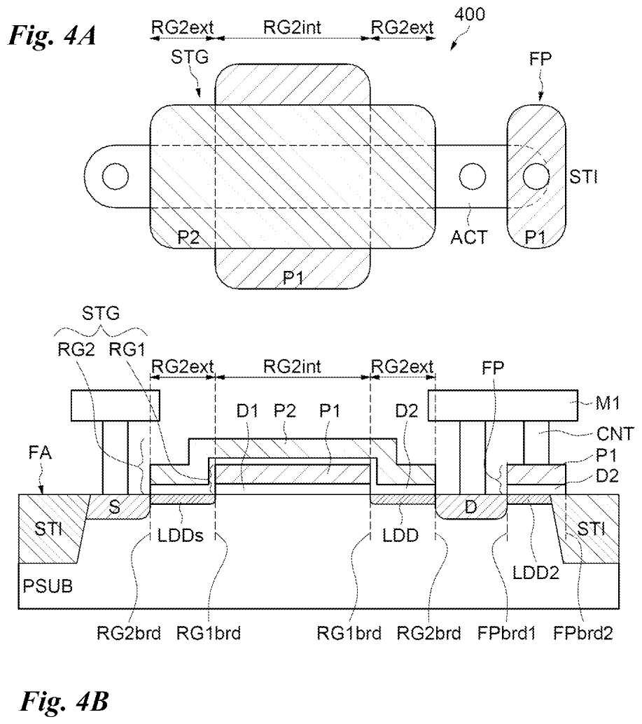

FIG. 4A, 4B illustrates a top view and a sectional view of a second example of transistor 400 adapted for high voltages, typically greater than 12V, alternatively to the transistor 200 previously described in relation to FIG. 2A, 2B.

The common elements of the transistor 400 with the transistor 200 described in relation to FIG. 2A, 2B bear the same references and will not all be detailed again.

In particular, the gate structure STG, the source S and drain D conduction regions, and the lightly doped conduction region LDDs, LDD located under the gate structure STG of the transistor 400 are identical to the respective elements of the transistor 200 described in relation to FIG. 2A, 2B.

In this alternative of the transistor 400, the field plate FP has the same nature and the same composition as the first gate region RG1, which are in this respect formed during the same manufacturing steps (see FIG. 8). Thus, the third conductive layer P1 of the field plate FP has the same composition (polysilicon) and the same (measurable) thickness as the first conductive layer P1 of the first gate region RG1; and the third dielectric layer D1 of the field plate FP has the same composition (silicon oxide) and the same (measurable) thickness as the first dielectric layer D1 of the first gate region RG1. Typically, the thicknesses of the first conductive layer P1 and of the first dielectric layer D1 are respectively less than the thicknesses of the second conductive layer P2 and of the second dielectric layer D2.

Here again, the field plate FP can advantageously be electrically connected to the drain region D, in order to reinforce the voltage withstand of the PN junction by field effect, and thus increase the avalanche voltage of the transistor 400.

In this framework, the field plate FP produces the same self-aligned mask effect for the implantation of the lightly doped conduction region LDDs, LDDs as the first gate region RG1. In other words, the lightly doped conduction region LDD2 is not implanted under the field plate FP while implanting the lightly doped conduction region LDDs, LDD under the gate structure STG.

This being the case, the implantation of the conduction regions S, D is done with a greater concentration and a greater energy than the implantation of the lightly doped conduction region LDDs, LDD, so that the first conductive layer P1 and the first dielectric layer D1 are partially permeable to the implantation of the conduction regions S, D.

Consequently, a second lightly doped conduction region LDD2 is implanted in the substrate PSUB through the field plate FP, when implanting the conduction regions S, D. The second lightly doped conduction region LDD2 has a concentration of dopants less than the concentration of the conduction regions S, D, and extends into the substrate PSUB from the front face FA to a depth less than the depth of the conduction regions S, D.

Thus, similarly to the example described in relation to FIG. 2A, 2B, the lightly doped conduction regions LDD, LDD2 extend on either side of the drain region D under the gate structure STG from the edge of the second gate region RG2brd and under the field plate FP from the edge of the field plate FPbrd1, plumb with which the drain region D is located.

Here again, the presence of the second lightly doped conduction region LDD2 under the field plate PL allows to increase the avalanche voltage of the transistor 200.

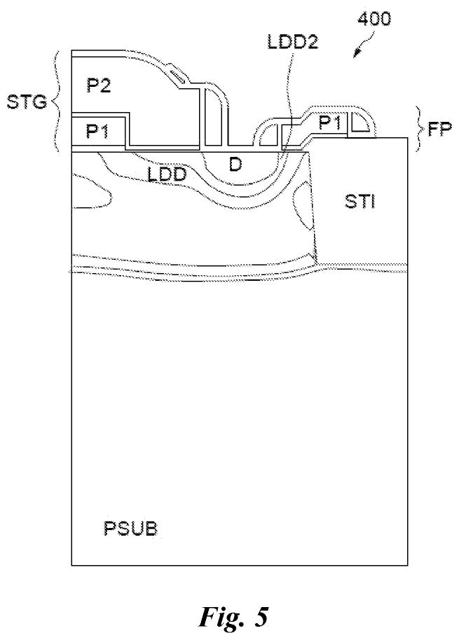

Reference is made in this respect to FIG. 5.

FIG. 5 shows a part of the sectional view of the transistor 400 of FIG. 4A, 4B which shows the concentration of dopants in the substrate PSUB, and in particular in the drain region D and the lightly doped conduction regions LDD, LDD2 under the gate structure STG and under the field plate FP.

Similarly to the morphology of the concentrations of dopants around the drain region D, LDD, LDD2 described in relation to FIG. 3, the presence of the second lightly doped conduction region LDD2 under the field plate FP causes the PN junction between the drain region D and the substrate PSUB not to include a locality having a high dopant concentration. Thus, the PN junction between the drain region D and the substrate PSUB is able to withstand higher voltages without producing an avalanche phenomenon.

Moreover, the embodiments of the transistor 200, 400 described previously in relation to FIGS. 2A, 2B to 5 write the presence of the field plate FP located on the external side (in the first direction, that is to say in the length of the active region ACT) of the drain conduction region D. This is justified by the fact that avalanche phenomena typically occur on the drain D side of the high voltage transistors. However, in particular applications, it may be desirable to improve the voltage withstand of the PN junction between the source S and the substrate PSUB. In this respect, the field plate FP as well as the lightly doped conduction region LDD2 under the field plate can perfectly be made symmetrically on the side of the source conduction region S, in order to obtain the same effects therein.

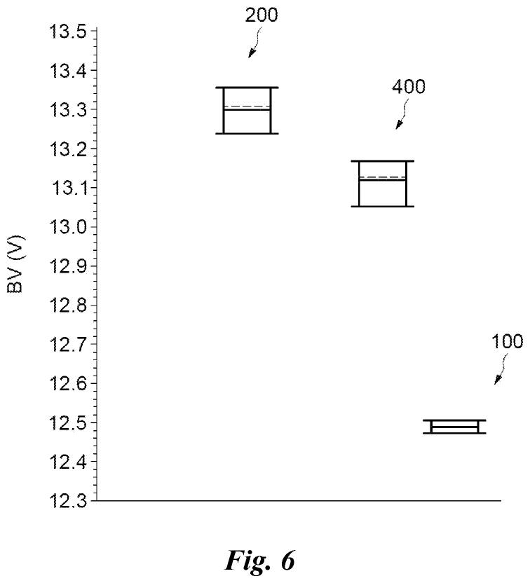

FIG. 6 shows measured results of avalanche voltages BV, between the drain region D and the substrate PSUB of embodiments of transistors 200 as described in relation to FIG. 2A, 2B, of embodiments of transistors 400 as described in relation to FIG. 4A, 4B, and embodiments of conventional transistors 100 as described in relation to FIG. 1.

The avalanche voltages BV of conventional transistors 100 are comprised between 12.46V and 12.5V. The avalanche voltages BV of transistors 200 are comprised between 13.22V and 13.36V. The avalanche voltages BV of the transistors 400 are comprised between 13.05V and 13.18V.

In other words, the presence of the field plate PL and of the lightly doped conduction region LDD2 under the field plate allows to increase the avalanche voltage of the high voltage transistors 200, 400 by substantially 1V, compared to a conventional high voltage transistor 100.

Besides being an advantage in itself, the gain of substantially 1V on the avalanche voltage BV can be particularly beneficial for non-volatile memory technologies such as EEPROM.

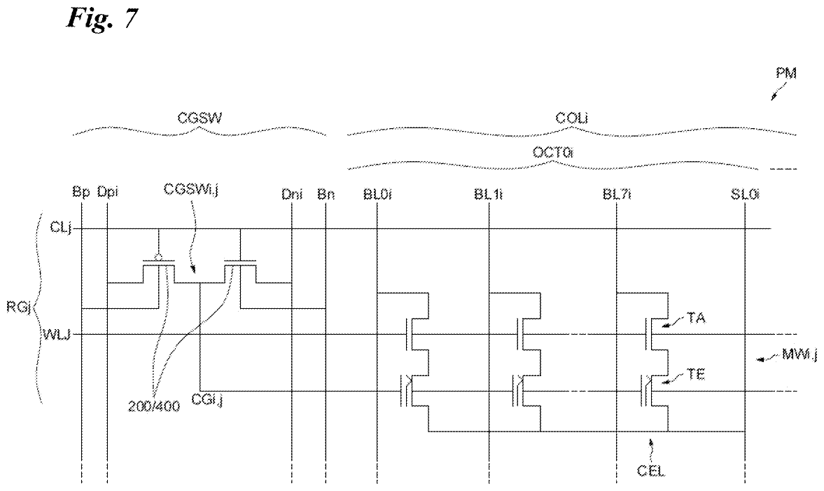

Reference is made in this respect to FIG. 7.

FIG. 7 shows a portion of a memory plane PM of an EEPROM type memory, in particular a memory word MWi,j belonging to a row RGj and to a column COLi. The memory word MWij comprises at least one byte OCT0i, for example 4 bytes, of eight memory cells CEL each. Each memory cell CEL includes an access transistor TA and a state transistor TE having a floating gate and a control gate. The access transistor TA and the state transistor TE are coupled in series between a bit line BL0i-BL7i individually coupled to the drain of the access transistor TA, and a source line SL0i coupled to the source of the state transistor TE. The source line SL0i can be common for the memory cells CEL belonging to one or more byte(s) OCT0i, or else to all the memory cells CEL of the memory plane PM.

The gates of the access transistors TA of all the memory cells CEL of the same row RGj are coupled to a word line WLj dedicated to each row.

The control gates of the state transistors TE of the memory cells of the same memory word MWij are coupled to a control gate line CGi,j dedicated to a memory word MWij of a column COLi and of a row RGj.

Access (decoding) to a control gate line CGi,j in the memory plane PM is done by means of a control gate switch circuit CGSWi,j located in a region CGSW of the memory plane PM near the word memory MWij respectively.

Each control gate switch circuit CGSWi,j may include an inverter circuit including a high voltage PMOS transistor and a high voltage NMOS transistor. The high voltage PMOS and NMOS transistors are advantageously embodiments of high voltage transistors 200 described in relation to FIG. 2A, 2B or embodiments of high voltage transistors 400 described in relation to FIG. 4A, 4B.

The PMOS and NMOS transistors 200/400 of the control gate switch circuit CGSWi,j are controlled by a control signal on their gates, transmitted on a common control line CLj and dedicated to each row RGj.

The drains of the complementary transistors 200/400 of the inverters of the respective switch circuits CGSWi,j are coupled to common and dedicated bias lines Dpi, Dni for each column COLi. Well bias lines Bn, Bp can allow to bias the complementary wells containing the PMOS and NMOS transistors. The sources of the complementary transistors 200/400 of the inverters of the switch circuits CGSWi,j are coupled to the lines of the respective control gates CGi,j.

Thus, the control line CLj of the row RGj and the bias lines Dpi, Dni of the column COLi allow to transmit a bias selectively on the control gate line CGi,j of the memory word MWi,j belonging to the column COLi and to the row RGj.

In memory cell write operations CEL, the write voltages transmitted on the control gate line CGi,j are adapted to produce an injection of charges into the floating gate of the state transistor TE, by Fowler-Nordheim effect through a tunnel oxide thickness.

The write voltages transmitted on the bias lines Dpi, Dni are typically 15V, with a bias of the wells Bn at 3V and the wells Bp at 15V, so as not to exceed the avalanche voltage of the transistors 200/400 typically close to 12V.

However, the gain of substantially 1V on the avalanche voltages BV of the transistors 200/400 of the control gate switch circuit CGSWi,j can allow, for a given current budget, to use higher write voltages in the memory. This would allow to increase the thickness of the oxide tunnel for better data retention, or to reduce the time of write cycles.

Indeed, a 500 mV increase in the write voltage can allow a 0.3 to 0.4 nm (nanometer) increase in tunnel oxide thickness, providing a factor of 10 improvement in data retention; or allow a division by 2 of the duration of the write cycles.

Alternatively, the gain of substantially 1V of the avalanche voltage can allow to reduce the consumption budget of the high voltage circuit, including many narrow transistors in the decoders and the control gate switch circuits CGSWi,j of the memory plane PM.

Another advantage of the transistors 200, 400 described in relation to FIGS. 2A, 2B and 4A, 4B of having, on the same transistor 200/400, both the benefit of the low current in the blocked state (usually “Ioff”) of the transistors conventionally narrow-channel transistors (that is to say across the width of the active region ACT), and benefit from the high avalanche voltage of conventionally wide-channel transistors (that is to say across the width of the active region ACT).

FIG. 8 illustrates an example of a manufacturing method 800 for transistors 200, 400 described in relation to FIGS. 2A, 2B and 4A, 4B.

The method 800 comprises a formation of at least one transistor including in particular: a formation 802-804, 806-808 of a separate gate structure STG and field plate FP, disposed on a front face of a semiconductor substrate; and a formation 809 of an S/D doped conduction region in the semiconductor substrate located plumb with an edge of the gate structure RG2brd and plumb with an edge of the field plate FPbrd.

The method 800 comprises a formation 801 of a dielectric volume of a shallow isolation trench STI, allowing in particular to define the active region ACT of the transistor 200/400.

The method 800 then comprises a formation 802 of a first dielectric layer D1 on the front face of the substrate, then a formation 803 of a first conductive layer P1 on the first dielectric layer D1 and then an etching 804 of the first conductive layer P1 delimiting the first gate region RG1.

Within the framework of the example of transistor 400 described in relation to FIG. 4A, 4B, the etching 804 of the first conductive layer P1 is configured to also delimit the field plate FP. Thus, the formation of the field plate FP is implemented simultaneously with the formation steps 802, 803 and with the etching step 804 of the first gate region RG1.

The etching 804 is configured to selectively etch the polycrystalline silicon faster than the silicon oxide of the first dielectric layer D1. This being the case, the etching 804 is typically calibrated to “over-etch” the first conductive layer P1, that is to say to remove a thickness greater than the actual thickness of the first conductive layer P1, in order to avoid any residue of polycrystalline silicon. This over-etching removes part of the first dielectric layer D1 not located under the gate, and there remains a residual thickness of the first dielectric layer D1.

The method 800 then comprises a formation 805 of a lightly doped conduction region LDDs, LDD, LDD2 implanted in the semiconductor substrate, in a self-aligned manner on the first gate region RG1, and optionally on the field plate formed during the steps 802, 803 and 804.

The implantation 805 is implemented with a second concentration lower than the first concentration of step 809 and with a second energy lower than the first energy of step 809.

The method 800 then comprises a formation 806 of a second dielectric layer D2, on the obtained structure, then a formation 807 of a second conductive layer P2 on the second dielectric layer D2.

The method 800 then comprises an etching 808 of the second conductive layer P2 delimiting a second gate region RG2. The etching 808 is configured so that the second gate region RG2 includes an internal portion RG2int on the first gate region and an external portion RG2ext projecting outside the first gate region on the front face of the substrate.

Within the framework of the example of transistor 200 described in relation to FIG. 2A, 2B, the etching 808 of the second conductive layer P2 is configured to also delimit the field plate FP. Thus, the formation of the field plate FP is implemented simultaneously with the formation steps 806, 807 and with the etching step 808 of the second gate region RG2. During steps 806, 807 and 808, the active region covered by the (future) field plate FP includes the lightly doped conduction region LDD2 formed during the implantation step 805.

The formation 806 of the second dielectric layer D2 stacks on the residual thickness of the first dielectric layer D1, at the places where the residual thickness of D1 is present. Thus, in absolute terms, under the external portion RG2ext of the second gate region RG2 and under the field plate FP in the example of the transistor 200 described in relation to FIG. 2A, 2B, the second dielectric layer D2 comprises a stack of residue of the partially etched first dielectric layer D1 (for example going from 22 nm to 16 nm in thickness after etching 804), and of the second dielectric layer added in step 806 (for example approximately 16 nm in thickness, for a total of about 32 nm thick). This stack allows to ensure the gate-source and gate-drain voltage withstand of the second dielectric layer D2 at high voltages of the order of 12V to 13V.

The method 800 then comprises a formation 809 of the conduction regions S/D, comprising an implantation of self-aligned dopants on the second gate region RG2, at a first concentration higher than the second concentration of step 805 and with a first energy greater than the second energy of step 805.

Simultaneously, within the framework of the example of transistor 400 described in relation to FIG. 4A, 4B, a formation 809 of the lightly doped conduction region LDD2 under the field plate FP is implemented through the field plate FP during the implantation 809 of the conduction regions S/D.

Thus, at this step of the method 800, in the context of the two examples of transistors 200, 400 described in relation to FIGS. 2A, 2B and 4A, 4B, the lightly doped conduction region LDDs, LDD, LDD2 extends on either side of the conduction region D under the gate structure STG from the edge of the gate structure and under the field plate FP from the edge of the field plate.

The method 800 then comprises a formation 810 of an electrical connection, typically by means of a metal contact pillar CNT and a metal track M1, connecting the field plate and the conduction region.

An integrated circuit may be summarized as including at least one transistor (200, 400) including a separate gate structure (STG) and field plate (FP), disposed on a front face (FA) of a semiconductor substrate (PSUB), and a doped conduction region (D) in the semiconductor substrate located plumb with an edge of the gate structure (RG2brd) and plumb with an edge of the field plate (FPbrd1).

Said at least one transistor (200, 400) may further include a lightly doped conduction region (LDD, LDD2) implanted in the semiconductor substrate, extending on either side of the conduction region (D) under the gate structure (STG) from said edge of the gate structure (RG2brd) and under the field plate (FP) from said edge of the field plate (FPbrd1).

The conduction region (D) may have a first dopant concentration and may extend into the substrate (PSUB) from the front face (FA) to a first depth, and the lightly doped conduction (LDD, LDD2) may have a second dopant concentration lower than the first concentration, and may extend into the substrate (PSUB) from the front face (FA) to a second depth less than the first depth.

The gate structure (STG) may include a first gate region (RG1) and a second gate region (RG2), the first gate region (RG1) including a first conductive layer (P1) disposed on a first dielectric layer (D1) and being located on the front face of the substrate (FA), the second gate region (RG2) including a second conductive layer (P2) disposed on a second dielectric layer (D2), the second gate region (RG2) including an internal portion (RG2int) on the first gate region (RG1) and an external portion (RG2ext) projecting from the first gate region (RG1) on the front face of the substrate (FA), the conduction region (D) being located plumb with an edge (RG2brd) of the external portion of the second gate region (RG2ext).

The lightly doped conduction region (LDD) may extend under the external portion of the second gate region (RG2ext).

The field plate (FP) may include a third conductive layer (P2) disposed on a third dielectric layer (D2) and may be located on the front face of the substrate (FA), the third conductive layer (P2) having the same composition and the same thickness as the second conductive layer (P2), the third dielectric layer (D2) having the same composition and the same thickness as the second dielectric layer (D2) of the external portion (RG2ext) of the second gate region (RG2).

The field plate (FP) may include a third conductive layer (P1) disposed on a third dielectric layer (D1) and may be located on the front face of the substrate (F1), the third conductive layer (P1) having the same composition and the same thickness as the first conductive layer (P1), the third dielectric layer (D1) having the same composition and the same thickness as the first dielectric layer (D1).

The field plate (FP) may be electrically connected (CNT, M1) to the conduction region (D). The edge of the field plate (FPbrd2) opposite said edge (FRbrd1) plumb with the conduction region (D) may be located above a dielectric volume of a shallow isolation trench (STI).

A method for manufacturing an integrated circuit may be summarized as including at least a formation (800) of a transistor including: a formation (802-804, 806-808) of a separate gate structure (STG) and field plate (FP), disposed on a front face of a semiconductor substrate; and a formation (809) of a doped conduction region (S/D) in the semiconductor substrate located plumb with an edge of the gate structure (RG2brd) and plumb with an edge of the field plate (FPbrd).

Said at least one formation (800) of the transistor may further include: a formation (805) of a lightly doped conduction region (LDD) implanted in the semiconductor substrate, extending on either side of the conduction region (D) under the gate structure (STG) from said edge of the gate structure and under the field plate (FP) from said edge of the field plate.

The formation (809) of the conduction region (S/D) may include an implantation of dopants at a first concentration and with a first energy, and the formation (805) of the lightly doped conduction (LDD) may include an implantation of dopants at a second concentration lower than the first concentration and at a second energy lower than the first energy.

The formation of the gate structure may include a formation (802) of a first dielectric layer (D1) on the front face of the substrate, a formation (803) of a first conductive layer (P1) on the first dielectric layer (D1) and an etching (804) of the first conductive layer (P1) delimiting a first gate region; a formation (806) of a second dielectric layer (D2), a formation (807) of a second conductive layer (P2) on the second dielectric layer (D2), and an etching (808) of the second conductive layer (P2) delimiting a second gate region, so that the second gate region includes an internal portion (RG2int) on the first gate region and an external portion (RG2ext) projecting from the first gate region on the front face of the substrate; and the formation (809) of the conduction region (S/D) comprising an implantation of self-aligned dopants on the second gate region (D2, P2).

The formation (805) of the lightly doped conduction region (LDD) may include an implantation of self-aligned dopants on the first gate region (D1, P1), before the steps of forming the second gate region.

The formation of the field plate (806-808) may include a formation (806) of a third dielectric layer (D2) on the front face of the substrate, a formation (807) of a third conductive layer (P2) on the third dielectric layer and an etching (808) of the third conductive layer (P2) delimiting the field plate, simultaneously with the respective formations (806, 807) and an etching (808) of the second gate region (D2, P2).

The formation of the field plate (802-804) may include a formation (802) of a third dielectric layer (D1) on the front face of the substrate, a formation (803) of a third conductive layer (P1) on the third dielectric layer and an etching (804) of the third conductive layer (P1) delimiting the field plate, simultaneously with the respective formations (802, 803) and etching (804) of the first gate region (D1, P1), the formation (809) of the lightly doped conduction region (LDD2) may include an implantation of dopants through the field plate during the implantation (809) of the conduction region (S/D).

The method may further include a formation (810) of an electrical connection (CNT-M1) between the field plate and the conduction region.

The method may include a formation (801), a dielectric volume of a shallow isolation trench (STI) prior to the formation of the field plate, the formation of the field plate comprising a delimitation of the field plate (GRV1, GRV2) so that the edge of the field plate opposite said edge plumb with the conduction region is located above the dielectric volume of the Shallow Isolation Trench (STI).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated circuit, comprising:
at least one transistor including:
a semiconductor substrate having a front face;
a gate structure including a first dielectric layer, a first conductive layer, a second dielectric layer, and a second conductive layer;
a field plate physically separated from the gate structure and disposed on the front face of the semiconductor substrate, the field plate including a third dielectric layer and a third conductive layer; and
a doped conduction region in the semiconductor substrate located transverse with an edge of the gate structure that is facing the field plate and transverse with an edge of the field plate that is facing the edge of the gate structure.

2. The integrated circuit according to claim 1, wherein said at least one transistor further includes a lightly doped conduction region implanted in the semiconductor substrate, extending on either side of the conduction region under the gate structure from the edge of the gate structure and under the field plate from the edge of the field plate.

3. The integrated circuit according to claim 2, wherein the conduction region has a first dopant concentration and extends into the substrate from the front face to a first depth, and the lightly doped conduction has a second dopant concentration lower than the first concentration, and extends into the substrate from the front face to a second depth less than the first depth.

4. The integrated circuit according to claim 1, wherein the gate structure includes a first gate region and a second gate region, the first gate region including the first conductive layer disposed on the first dielectric layer and being located on the front face of the substrate, the second gate region including the second conductive layer disposed on the second dielectric layer, the second gate region including an internal portion on the first gate region and an external portion projecting from the first gate region on the front face of the substrate, the conduction region being located transverse with an edge of the external portion of the second gate region.

5. The integrated circuit according to claim 4, wherein the lightly doped conduction region extends under the external portion of the second gate region.

6. The integrated circuit according to claim 4, wherein the field plate comprises the third conductive layer disposed on the third dielectric layer and is located on the front face of the substrate, the third conductive layer having the same composition and the same thickness as the second conductive layer, the third dielectric layer having the same composition and the same thickness as the second dielectric layer of the external portion of the second gate region.

7. The integrated circuit according to claim 4, wherein the field plate comprises a third conductive layer disposed on a third dielectric layer and is located on the front face of the substrate, the third conductive layer having the same composition and the same thickness as the first conductive layer, the third dielectric layer having the same composition and the same thickness as the first dielectric layer.

8. The integrated circuit according to claim 1, wherein the field plate is electrically connected to the conduction region.

9. The integrated circuit according to claim 1, wherein the edge of the field plate opposite said edge transverse with the conduction region is located above a dielectric volume of a shallow isolation trench.

10. A method for manufacturing an integrated circuit comprising:
forming a transistor including:
forming a semiconductor substrate having a front face;
forming a gate structure including a first dielectric layer, a first conductive layer, a second dielectric layer, and a second conductive layer;
forming a field plate separated from the gate structure and disposed on the front face of the semiconductor substrate, the field plate including a third dielectric layer and a third conductive layer; and
forming a doped conduction region in the semiconductor substrate located between the gate structure and the field plate.

11. The method according to claim 10, wherein forming the transistor further includes:
forming a lightly doped conduction region implanted in the semiconductor substrate, extending on either side of the conduction region under the gate structure from said edge of the gate structure and under the field plate from said edge of the field plate.

12. The method according to claim 11, wherein forming the conduction region comprises:
implanting dopants at a first concentration and with a first energy; and
forming the lightly doped conduction comprises:
implanting dopants at a second concentration lower than the first concentration and at a second energy lower than the first energy.

13. The method according to claim 9, wherein forming the gate structure includes:
forming the first dielectric layer on the front face of the substrate;
forming the first conductive layer on the first dielectric layer;
etching the first conductive layer to delimit a first gate region;
forming the second dielectric layer;
forming the second conductive layer on the second dielectric layer;
etching the second conductive layer to delimit a second gate region, the second gate region including an internal portion on the first gate region and an external portion projecting from the first gate region on the front face of the substrate; and
the conduction region comprising implanting a plurality of self-aligned dopants on the second gate region.

14. The method according to claim 13, wherein forming the lightly doped conduction region comprises implanting the plurality of self-aligned dopants on the first gate region, before forming the second gate region.

15. The method according to claim 13, wherein forming the field plate comprises:
forming the third dielectric layer on the front face of the substrate;
forming the third conductive layer on the third dielectric layer;
etching the third conductive layer to delimit the field plate; and
etching the second gate region.

16. The method according to claim 13, wherein forming the field plate comprises:
forming the third dielectric layer on the front face of the substrate;
forming the third conductive layer on the third dielectric layer;
etching the third conductive layer to delimit the field plate;
etching the first gate region;
forming the lightly doped conduction region by implanting dopants through the field plate during the implanting of the conduction region.

17. The method according to claim 10, further comprising forming an electrical connection between the field plate and the conduction region.

18. The method according to claim 10, comprising, forming a dielectric volume of a shallow isolation trench prior to forming the field plate, forming the field plate comprising delimitating the field plate so that an edge of the field plate is located above the dielectric volume of the Shallow Isolation Trench.

19. A transistor device, comprising:
a semiconductor substrate having a front face;
a gate structure on the front face of the substrate, the gate structure comprising:
a first dielectric layer having a first end and a second end;
a first conductive layer on the first dielectric layer, the first conductive layer having a first end coplanar with the first end of the first dielectric layer and a second end coplanar with the second end of the first dielectric layer;
a second dielectric layer on the first conductive layer and extending onto the front face of the semiconductor substrate; and
a second conductive layer on the second dielectric layer;
a field plate physically separated from the gate structure and on the front face of the substrate, the field plate comprising:
a third dielectric layer having a first end and a second end; and
a third conductive layer on the third dielectric layer, the third conductive layer having a first end coplanar with the first end of the third dielectric layer and a second end coplanar with the second end of the third dielectric layer; and
a doped conduction region in the semiconductor substrate located between the gate structure and the field plate.

20. The transistor device according to claim 1, wherein the third dielectric layer has a composition that are the same as a composition of the second dielectric layer and the third conductive layer has a composition that are the same as a composition of the second conductive layer.
